(19) United States
(12) Patent Application Publication
(10) Pub. No.: US 2026/0371512 A1
(43) Pub. Date: Nov. 19, 2026

(54) ELECTRICAL ISOLATION AND THERMAL REGULATION FOR HIGH VOLTAGE ELECTRICAL COMPONENTS

(71) Applicant: DH Technologies Development Pte. Ltd., Singapore (SG)

(72) Inventors: Manuel FAUR, Richmond Hill (CA); Ernesto GRADIN, York (CA)

(73) Assignee: DH Technologies Development Pte. Ltd., Singapore (SG)

(21) Appl. No.: 19/154,422

(22) PCT Filed: Feb. 7, 2024
(86) PCT No.: PCT/IB2024/051133

§ 371 Date: Aug. 7, 2025

Related U.S. Application Data
(60) Provisional application No. 63/443,814, filed on Feb. 7, 2023.

(51) Int. Cl. H05K 5/06; H01J 49/02; H01J 49/06; H01J 49/26

(52) U.S. Cl. CPC H05K 5/062; H01J 49/022; H01J 49/06; H01J 49/26

(57) ABSTRACT

A mass spectrometer includes at least one ion optic for influencing the trajectory of at least one ion in an ionized sample. A casing includes a plurality of walls. Power supply components are disposed in the casing for supplying power to the at least one ion optic. An expansion component is within the casing. An encapsulant is disposed in the casing and encapsulates the power supply components. The encapsulant is in contact with the expansion component.

### CROSS-REFERENCE TO RELATED APPLICATION

This application is being filed on Feb. 7, 2024, as a PCT International application and claims the benefit of and priority to U.S. Patent Application No. 63/443,814, filed on Feb. 7, 2023, the disclosure of which is hereby incorporated by reference in its entirety.

### BACKGROUND

Electrical circuits are used to power ion optics within mass spectrometry (MS) systems. Certain high voltage components of such circuits are often fully surrounded by an encapsulant, which electrically isolates the components to prevent short circuiting. The encapsulant aids in thermal regulation of the components, so as to prevent overheating. Encapsulant is introduced to a vessel or a casing surrounding the high voltage components in a flowable or molten state, after which it hardens or solidifies. The encapsulant is subject to expansion during operation of the high voltage components as the temperature generated by those components increases.

### SUMMARY

In one aspect, the technology relates to a mass spectrometer including: at least one ion optic for influencing the trajectory of at least one ion in an ionized sample; a casing which includes a plurality of walls; power supply components disposed in the casing for supplying power to the at least one ion optic; an expansion component within the casing; and an encapsulant disposed in the casing and encapsulating the power supply components, and wherein the encapsulant is in contact with the expansion component. In an example, the expansion component includes a compressible layer and a conductive layer, wherein the compressible layer is in contact with at least one wall of the plurality of walls, and wherein the conductive layer is disposed on a side of the compressible layer opposite the at least one wall, and wherein the encapsulant is in contact with the conductive layer. In another example, the at least one wall includes a face cover of the casing. In yet another example, the casing defines a casing volume and wherein the encapsulant includes an encapsulant volume less than the casing volume. In still another example, a portion of the casing and an exposed surface of the encapsulant at least partially define a void volume, and wherein the casing includes a removeable access cover adjacent the void volume.

In another example of the above aspect, the removeable access cover defines a vent opening. In an example, the casing defines an encapsulant inlet. In another example, the compressible layer includes at least one of a bladder, a bellows, a foam, and a bead. In yet another example, the expansion component is secured to at least two walls of the plurality of walls. In still another example, the expansion component is secured to the at least one wall via the conductive layer.

In another example of the above aspect, the casing and an exposed surface of the encapsulant at least partially define a void volume and wherein the expansion component extends into the void volume. In an example, the conductive layer includes a metallic foil.

In another aspect, the technology relates to a method of encapsulating at least a portion of a power supply circuit for a mass spectrometer, the method includes: disposing a plurality of casing walls at least partially around the portion of the power supply circuit, wherein the plurality of casing walls at least partially define a casing volume; securing an expansion component to at least one of the casing walls; and at least partially filling, with an encapsulant, the casing volume to an encapsulant volume less than the casing volume, wherein the expansion component is disposed between the encapsulant and at least one of the plurality of casing walls. In an example, the at least one of the plurality of casing walls includes a face cover secured to a plurality of perimeter walls of the plurality of casing walls. In another example, the expansion component includes a conductive layer for securing the expansion component to the face cover, and wherein a compressible layer of the expansion component is disposed between the conductive layer and the face cover. In yet another example, at least one of the plurality of casing walls defines a encapsulant inlet, and wherein filling the casing volume with the encapsulant includes filling the casing volume via the encapsulant inlet. In still another example, the method further includes securing an access cover to the plurality of casing walls, wherein the access cover defines a vent opening.

In another example of the above aspect, the encapsulant volume is below a lowermost edge of the access cover. In an example, the expansion component projects from the encapsulant volume. In another example, the method further includes securing to the plurality of casing walls, the at least one casing wall having secured thereto the expansion component. In yet another example, the compressible layer includes at least one of a bladder, a bellows, a foam, and a bead. In still another example, the conductive layer includes a metallic foil.

In another aspect, the technology relates to a method of manufacturing a power supply, the method includes: securing an expansion component to at least one wall of a power supply casing defining a casing volume; and at least partially filling the power supply casing with an encapsulant, wherein the encapsulant is in contact with the expansion component. In an example, securing the expansion component to the at least one wall of the power supply casing includes adhering a compressible layer of the expansion component to the at least one wall. In another example, securing the expansion component to the at least one wall of the power supply casing includes adhering a conductive layer of the expansion component to the at least one wall. In yet another example, a compressive layer of the expansion component is disposed against the at least one wall and biases a conductive portion of the expansion component against the encapsulant.

In another aspect, the technology relates to a method of powering at least one ion optic of a mass spectrometer, the method includes energizing a power supply for the at least one ion optic, wherein the power supply includes at least one power supply component disposed in an encapsulant, while biasing a conductive layer of an encapsulant expansion component against the encapsulant.

### BRIEF DESCRIPTION OF THE DRAWINGS

FIG. 1 is a schematic diagram of a mass spectrometry system.

FIG. 2 depicts a mass spectrometer wherein at least one quadrupole can be controlled to eject ions in a desired sequence.

FIG. 3 is a schematic diagram of an electrical component chassis for an MS system.

FIG. 4A depicts a front schematic view of a high voltage isolation case of the electrical component chassis of FIG. 3.

FIG. 4B depicts side sectional view of the high voltage isolation case of the electrical component chassis of FIG. 3.

FIG. 5 depicts a portion of a power supply casing and an expansion component utilized in the high voltage isolation case of FIGS. 4A and 4B.

FIG. 6 depicts a method of manufacturing a power supply.

FIG. 7 depicts a method of encapsulating at least a portion of a power supply circuit for a mass spectrometer.

FIG. 8 depicts a method of powering at least one ion optic of a mass spectrometer.

FIG. 9 depicts a block diagram of a computing device.

### DETAILED DESCRIPTION

The technologies described herein improve the stability of high voltage power supplies, e.g., for a mass spectrometry (MS) system. In an example, an expansion component including a compressible layer and a conductive layer are secured to at least one wall of a casing that surrounds certain high voltage components of an electrical circuit. This enables expansion of the encapsulant as it is exposed to the elevated temperatures generated by the high voltage components. By allowing for expansion of the encapsulant, the technologies described herein reduce component parameter (e.g., resistance) drift due to mechanical stress caused by encapsulant expansion. One benefit thereof is an improvement in the stability of the power supply. Further, the layered construction of the expansion component (e.g., using a conductive layer and a compressible layer) enables the conductive layer to act as an electrostatic shield, thus reducing or preventing high voltage discharges in any voids that may be present in the compressible layer (e.g., as typically present in a compressible foam).

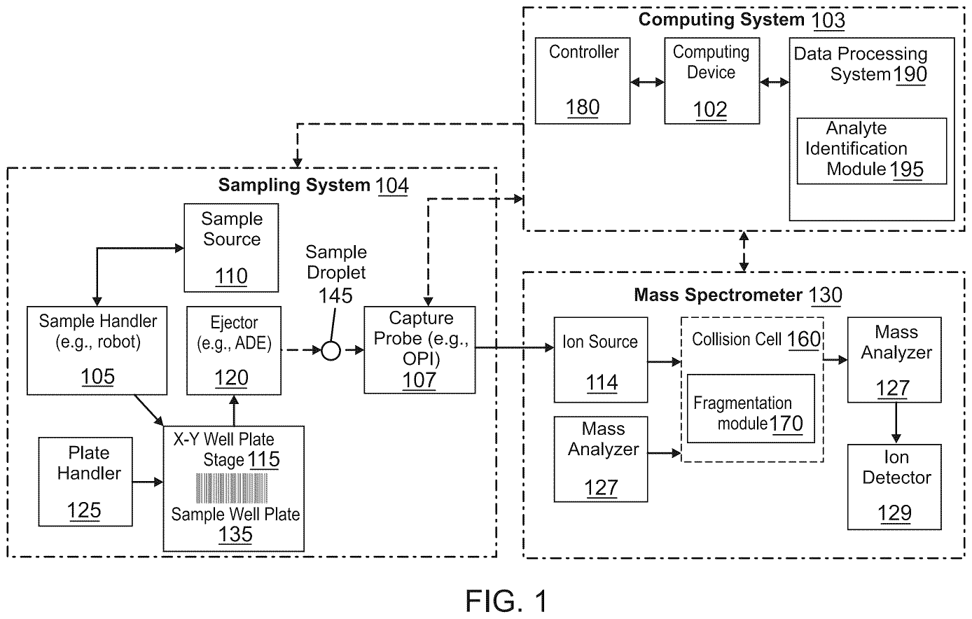

FIG. 1 is a schematic diagram illustrating the operation of an example system combining acoustic droplet ejection (ADE) with an open port interface (OPI) sampling interface and electrospray ionization (ESI) source. In the illustrated example, the system 100 is operative to perform, e.g., mass spectrometry analysis. Similar to the system 100 of FIG. 1, the system 100 includes a sampling system 104, a MS 130, and a computing system 103.

In various aspects, the sampling system 104 may include at least one of a sample source 112 (such as a reservoir or well plate), a sample handler 105, a capture probe 107, an X-Y well plate stage 115, an ejector 120, and a plate handler 125. The sample source 112 and the sample handler 105 are operative to retrieve collections of samples from the sample source 112 and to deliver the retrieved collections to capture locations associated with sample capture probe 107. The system 100 may be operative to independently capture selected ones of the plurality of samples at the capture locations, e.g., capture probe 107, to optionally dilute the samples and to transfer the captured samples to MS 130 for mass analysis. In some examples, the sample source 112 may include a set of well plates in a storage housing and/or liquid for adding to well plates 135. The sample source 112 may include part of a liquid handling system that manipulates and/or injects liquid into the well plates 135. The sample handler 105 includes one or more electro-mechanical devices (e.g., robotics, conveyor belts, stages, and the like) that are capable of transferring samples (e.g., well plates) from the sample source 112 to other components of the sampling system 104 and/or to other components, such as the ejector 120 and/or the capture probe 107. As an example, the sample handler 105 may transfer a sample well plate 135 to the ejector 120 or the plate handler 125.

In various aspects, the ejector 120 is operable to eject droplets of samples 145 from the wells of the well plate 135. The size of the droplet or sample may typically be from 1 to 15 nanoliters. The ejector 120 may be any type of suitable ejector, such as an acoustic ejector, a pneumatic ejector, or another type of contactless ejector. In an example, the plate handler 125 receives a well plate 135 from the sample handler 105. The plate handler 125 transports the well plate 135 to a capture location that may be aligned with the capture probe 107. Once in the capture location, the ejector 120 ejects droplets 145 from one or more wells of the well plate 135. The plate handler 125 may include one or more electro-mechanical devices, such as a translation stage 115 that translates the well plate 135 in an X-Y plane to align wells of the well plate 135 with the ejector 120 and/or or the capture probe 107.

In various aspects, the MS 130 includes at least one of an ion source (e.g., ionization source) 114, a mass analyzer 127, an ion detector 129, and a collision cell 160. The MS 130 can be operative, for example, through use of ion source(s) or generator(s) 114 to produce sample ions of the sample introduced into the MS 130. The collision cell 160 is operative to fragment the precursor ions produced by the ion source 114 to generate product ions (fragment ions) derived from the precursor ions. In various examples, the mass analyzer 127 may be before the collision cell. The MS 130 is further operative to filter and detect selected ions of interest from the sample ions through the use of the mass analyzer 127 and ion detector 129. The mass analyzer 127 is operative to analyze the sample ions and produce a mass spectrometry dataset including all ion current signals from the sample ions.

In some aspects, the MS 130 is operative to perform tandem mass spectrometry analysis through the use of the collision cell 160. The collision cell 160 may further include a fragmentation module 170 operative to apply an energy to the selected precursor ions and cause the selected precursor ions to undergo fragmentation and generate product ions. The fragmentation module 170 may include at least one of collision induced dissociation (CID), surface induced dissociation (SID), electron capture dissociation (ECD), electron transfer dissociation (ETD), metastable-atom bombardment, photo-fragmentation, or combinations thereof.

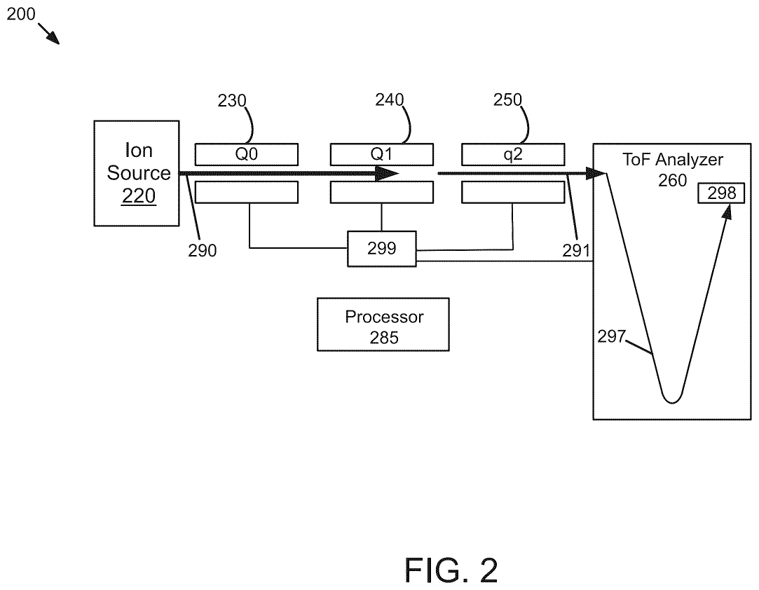

It will also be appreciated by a person skilled in the art and in light of the teachings herein that the mass analyzer 127 can have a variety of configurations. Generally, the mass analyzer 127 is operative to process (e.g., filter, sort, dissociate, detect, etc.) sample ions generated by the ion source 114. By way of non-limiting example, the mass analyzer 127 may be a triple quadrupole mass spectrometer, or any other mass analyzer known in the art and modified in accordance with the teachings herein. An example of a particular mass analyzer includes a time-of-flight mass analyzer such as depicted in FIG. 2.

In various aspects, the computing system 103 may include a computing device 109 as described above, a controller 180, and a data processing system 190. The controller 180 may be in the form of electronic signal processors and in electrical communication with other subsystems within the system 100. The controller 180 may be operative to coordinate some or all of the operations of the pluralities of the various components of the system 100. In one example, the controller 180 may be a controller for the mass spectrometer 127 and may be used as the primary controller for controlling components in addition to those components housed within the mass spectrometer 127. As such, the controller 180 may be considered the main or central controller that orchestrates, or communicates with, the other controllers to carry out the operations discussed herein in a more efficient manner.

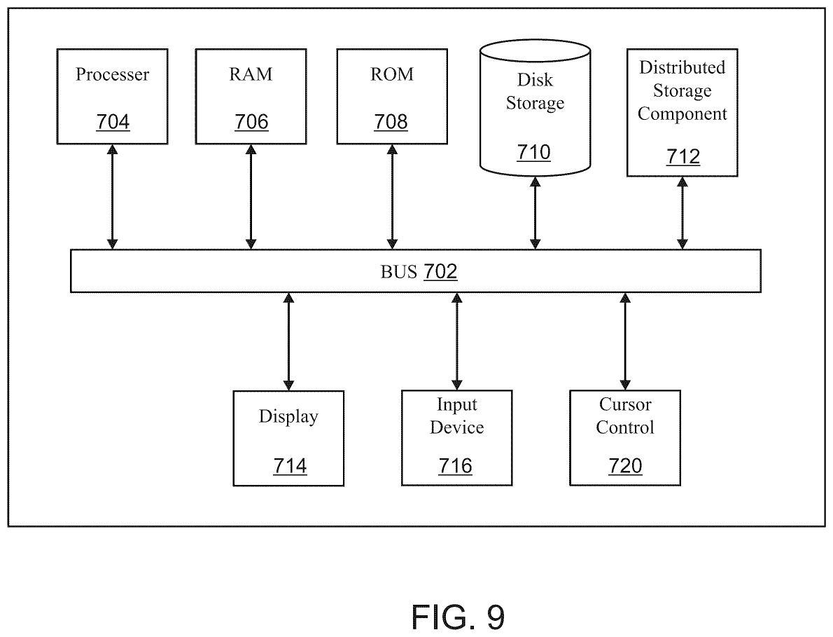

In various aspects, the data processing system 190 may include various components and modules operative to process mass spectrometry data and to provide real-time feedback to users and other subsystems. In some examples, the data processing system 190 further includes an analyte identification module 195. The analyte identification module 195 may be operative to perform a library search and predict compound identity of a target analyte in a test sample, optionally through use of the trained machine learning algorithm. In various examples, the computing system 103 may be similar to the computing device 900 described in greater detail below with respect to FIG. 9.

In operation, the sampling system 104 (including sample source 112 and sample handler 105) can iteratively deliver independent samples from a plurality of sample sources (e.g., a droplet from a well of well plate 135) to the capture probe 107. The capture probe 107 can dilute and transport each such delivered sample to the MS 130 disposed downstream of the capture probe 107 for ionizing the diluted sample. The mass analyzer 127 can receive generated ions from the ion source 114 and/or the collision cell 160 for mass analysis. The mass analyzer 127 is operative to selectively separate ions of interest from generated ions received from the ion source 114 and to deliver the ions of interest to the ion detector 129 that generates a mass spectrometer signal indicative of detected ions to the computing system 103. In some aspects, the separate ions of interest may be indicated in an analysis instruction associated with that sample. In some aspects, the separate ions of interest may be indicated in an analysis instruction identified by an indicia physically associated with the plurality of samples. The system 100 may include, e.g., a commercial computer in operative communication with a MS 130 and a controller for the capture probe 107, which may include, for example, a SCIEX OS computer available from SCIEX. The SCIEX OS computer includes a control controller for the capture probe 107, represented for example by SCIEX open port interface software, and a controller for the MS 130, which may be the SCIEX OS computer. The MS 130 and the controller for capture probe 107 may be further in operative communication with an ejector 120 and an X-Y well plate stage 115, which may be, for example, a liquid droplet ejector with embedded computer or processor. For the purposes of this disclosure, these distributed controller components may collectively be considered to be a system controller, and depending upon the configuration, may be centralized or distributed as is the case here. For instance, one of the controllers or controller components may send signals to the other controllers to control the respective devices.

FIG. 2 depicts a particular type of mass spectrometer 200, the mass spectrometer 200 comprising a system of ion optics including an ion guide 230, a quadrupole mass analyzer 240, a collision cell 250 (e.g. a fragmentation module) and a time of flight (ToF) mass analyzer 260. The mass spectrometer 200 is enabled to transmit an ion beam from ion source 220 through to ToF mass analyzer 260. In some embodiments, mass spectrometer 200 can further comprise a processor 285 for controlling operation of mass spectrometer 200, including but not limited to controlling ion source 220 to ionise the ionisable materials, and controlling transfer of ions between modules of mass spectrometer 200. In operation, ionisable materials are introduced into ion source 220. Ion source 220 generally ionises the ionisable materials to produce ions 290, in the form of an ion beam, which are transferred to the ion optics, which influence the trajectory of the ions 290. The ions are first transferred to ion guide 230 (also identified as Q0 , indicative that ion guide 230 takes no part in the mass analysis). Ions 290 are transferred from ion guide 230 to quadrupole mass analyzer 240 (also identified as Q1 ), which can operate as a mass filter. Filtered or unfiltered ions then enter collision cell 250 also identified as q2 which can be controlled to eject ions 291 in a desired sequence, as described below. In some embodiments, ions 291 can be fragmented in collision cell 250. It is understood that collision cell 250 can comprise any suitable multipole, including but not limited to a quadrupole, a hexapole, and an octopole. In some embodiments, collision cell 250 comprises a quadrupole, mechanically similar to quadrupole mass analyzer 240. Ions 291 are then transferred to ToF analyzer 260 for production of mass spectra. In doing so, ions 291 follow a path 297 through ToF mass analyzer 260 and impinge on a suitable detector surface 298, the time of flight it takes to travel path 297 being proportional to the square root of the mass to charge ratio of an ion.

Furthermore, while not depicted, mass spectrometer 200 can comprise any suitable number of vacuum pumps to provide a suitable vacuum in ion source 220, ion guide 230, quadrupole mass analyzer 240, collision cell 250 and/or ToF mass analyzer 260. It is understood that in some embodiments a vacuum differential can be created between certain elements of mass spectrometer 200: for example a vacuum differential is generally applied between ion source 220 and ion guide 230, such that ion source 220 is at atmospheric pressure and ion guide 230 is under vacuum. While also not depicted, mass spectrometer 200 can further comprise any suitable number of connectors, power sources, RF (radio-frequency) power sources, DC (direct current) power sources, gas sources (e.g. for ion source 220 and/or collision cell 250), and any other suitable components for enabling operation of mass spectrometer 200.

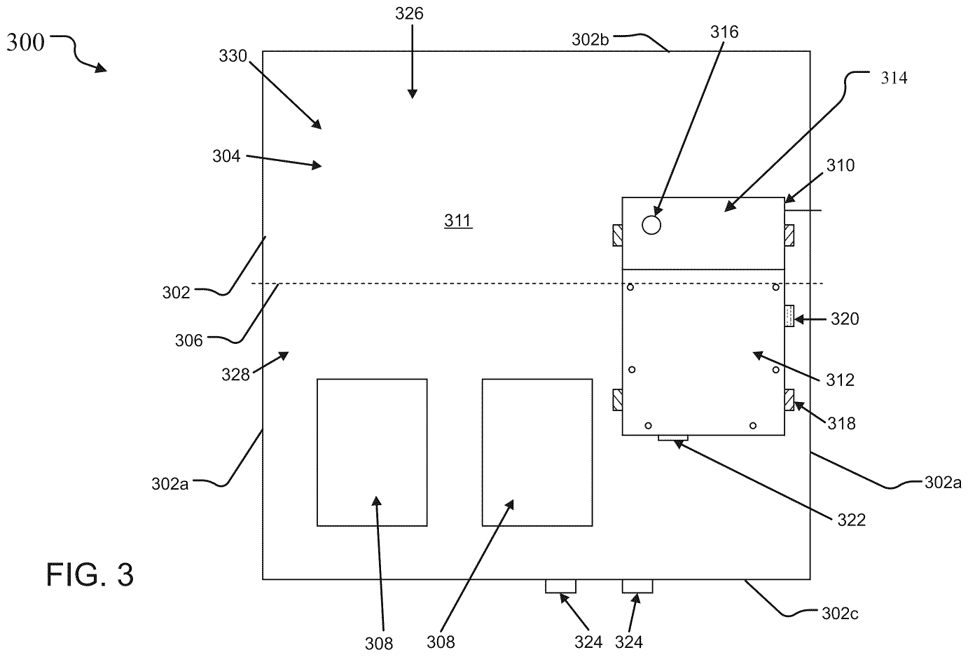

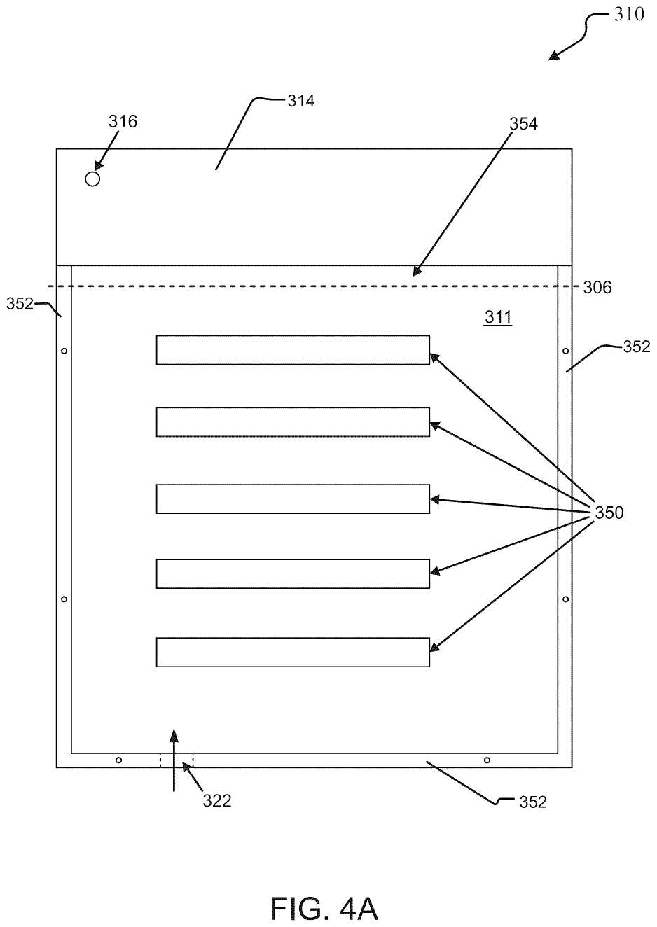

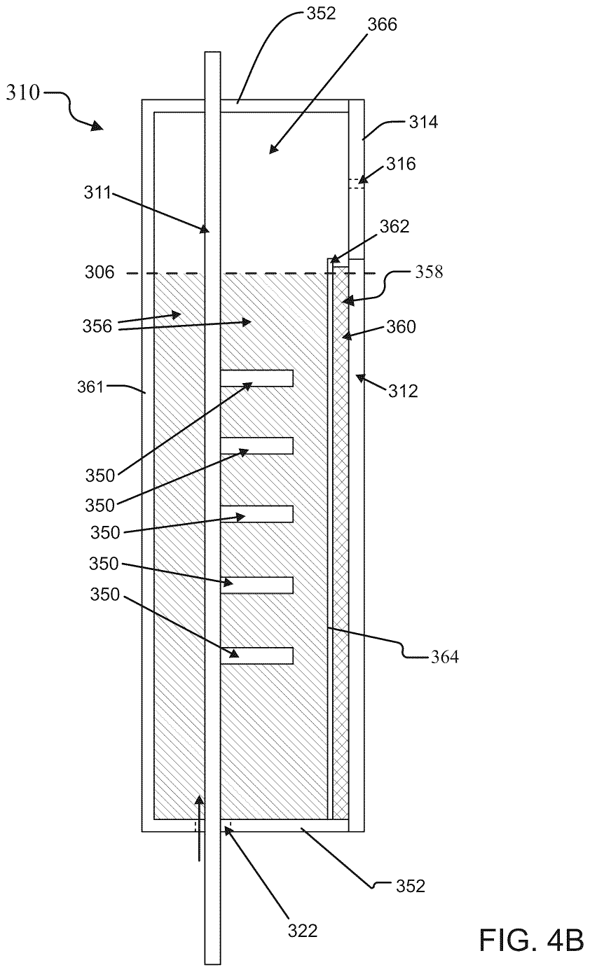

In particular, mass spectrometer 200 comprises a power source 299 for coupling RF and AC signals to provide power to a quadrupole in mass spectrometer 200, and specifically for providing power to the ion optics, including ion guide 230, quadrupole mass analyzer 240 (Q1 ), and collision cell 250 (q2 ). Further, power source 299 may provide power to the ToF mass analyzer 260, which may have multiple ion optic components therein, including for example one or more of ion guides, accelerators and reflectors. Power source 299 enables a quadrupole, such as collision cell 250, to be controlled to eject ions 291 in a desired sequence: for example in order of m/z ratio with heaviest ions (i.e. ions with a high m/z ratio) ejected first and lightest ions (i.e. ions with a low m/z ratio) ejected last. In depicted embodiments, power source 299 is connected to collision cell 250 such that fragmented ions are ejected in order of m/z ratio, and so that fragmented ions reach ToF mass analyzer 260 at substantially the same time. Power source 299 may be configured as described further in FIGS. 3-4B.

FIG. 3 is a schematic diagram of an electrical module chassis 300 for an MS system, which may contain a power source 299 such as depicted in FIG. 2. The chassis 300 may include a housing 302 that includes a plurality of walls 304 (in FIG. 3, two sidewalls 302a, an upper wall 302b, and a bottom wall 302c are depicted). The sidewalls 302 at least partially define an interior volume 304 of the electrical component chassis 300. One or more face walls may also be utilized to close the interior volume 304. The face walls are not depicted, so as to enable display of additional components within the interior volume 304. In examples, a single face wall may be secured to the plurality of walls 302 so as to close the interior volume 304. In other examples, a first face wall may extend from and be secured to the bottom wall 302c and lower portions of sidewalls 302a. This first face wall may extend up to about line 306. A second face wall may be secured to the upper wall 302b and upper portions of sidewalls 302a. This second face wall may abut the first face wall, for example, adjacent line 306.

The interior volume 304 may contain a number of electrical components 308, as well as a high voltage component isolation casing 310, which substantially surrounds a plurality of high voltage power supply components (depicted in FIGS. 4A-4B). Any of the electrical components 308, high voltage component casing 310 (or the high voltage components disposed therein) may be secured to a printed circuit board (PCB) 311 that is disposed in the chassis 300. In FIG. 3, the location of the PCB 311 is depicted generally within the interior volume 304 of the chassis 300. Discrete traces, chips, capacitors, and other components are not shown, but electrical components 308, the high voltage casing 310, and components located in the high voltage casing 310 may be secured directly to the PCB 311, as would be apparent to a person of skill in the art.

The high voltage component casing 310 includes a removable face cover 312 and a removable access cover 314. The high voltage component casing 310 may define a vent opening 316, that in this example is formed in the access cover 314. Further features of the high voltage component casing 310 includes one or more heating elements 318 and a temperature sensor 320. The high voltage component casing 310 further defines an encapsulant inlet 322, which in examples, may be an opening in wall of the casing 310 through which an electrical connection passes. Other electrical connections 324 may penetrate various walls of the chassis 300, such as the bottom wall 302c though these penetrations may be sealed. Various locations for inlets and vents are contemplated, with inlets located generally lower on the various components of the casing 310, and vents located generally higher on the casing 310.

Line 306 also defines a level to which the chassis 300 is filled with encapsulant, so as to isolate the desired high voltage components of a power supply circuit, as well as other components. Encapsulant is introduced to the chassis 300 as depicted by arrow 326. In examples, the encapsulant may be introduced 326 via an opening in an upper wall 302b of the chassis 300 until a level is reach generally coextensive with line 306. This results in a filled volume 328 and an unfilled volume 330. As the encapsulant is being introduced 326 to the interior volume 304 of the chassis 300, flowable encapsulant enters the high voltage component casing 310, for example, via the encapsulant inlet 322. Air present within the interior volume of the high voltage component casing 310 flows out of the vent opening 316. As such, an interior volume of the high voltage component casing 310 also fills with encapsulant.

FIG. 4A depicts a front schematic view of a high voltage component isolation case 310 of the electrical component chassis of FIG. 3, while FIG. 4B depicts a side sectional view of the high voltage component isolation case 310. FIGS. 4A and 4B are described concurrently for clarity, and certain components are not depicted in both figures. For example, in FIG. 4A, the removeable face cover 312 is not depicted so certain high voltage components 350 may be viewed. The high voltage components 350 are mounted to the PCB 311 described above in the context of FIG. 3. The high voltage component isolation case 310 includes a plurality of walls 352, the lowermost of which defines an encapsulant inlet 322. In examples, certain of the walls 352 may surround or substantially surround portions of the PCB 311. A removable access cover 314 defining a vent opening 316 is depicted in both FIGS. 4A and 4B. Together, the various walls (e.g., walls 352 and wall 361), and covers 312, 314 at least partially define a casing volume 354, into which an encapsulant 356 is at least partially filled, as described in more detail below.

In order to accommodate thermal expansion of the encapsulant 356 disposed in the casing volume 354, an expansion component 358 is disposed in contact with at least one of the walls 352 or the cover 312. The expansion component 358 includes a compressible layer 360 and a conductive layer 362. The compressible layer 360 accommodates expansion of the encapsulant 356 as heat from the high voltage components 350 causes expansion during operation of ion optics of an associated mass spectrometer. Further, heat is produced by heater components which stabilize the temperature of the casing; thus, the casing acts as an oven for the purpose of stabilizing temperature to prevent drift. In the depicted example, the compressible layer 360 may be a compressible foam such as an open-or closed-cell foam, a bladder or bellows (e.g., a closed pocket of material having disposed therein air or other gas-such materials may be similar in appearance to so-called “bubble wrap” packing material), a plurality of air-filled plastic beads,, or like materials that are compressible (typically due to the presence of air or other gas pockets therein). To avoid corona discharge within any air that may be present in the compressible layer 360, a conductive layer 362 is disposed between the encapsulant 356 and the compressible layer 360, which in the depicted example is the face cover 312. The conductive layer is electrically connected and held at a potential such that the electric field within the compressible material is low. Materials utilized for the conductive layer 362 may be any conductive metal or other material, e.g., copper, zinc, gold, silver, or other metals. In still other examples, the conductive layer and compressible lay may be in the form of a single, unitary component (e.g., a foam) displaying both conductive and compressible properties.

Once the case 310 is (e.g., the walls 352, 361, and face cover 312) is assembled, encapsulant 356 may be introduced to the chassis, such as depicted in FIG. 3. As the encapsulant 356 fills the chassis, the encapsulant 356 enters the case 310 via the encapsulant inlet 322, thereby introducing I the encapsulant 356 to an interior of the case 310. Air within the case 310 is expelled via the vent opening 316 as the casing volume 354 fills with encapsulant 356. The filling process continues until the encapsulant 356 reaches a filled level consistent with line 306 (as depicted in FIG. 3).

The volume of the case 310 below line 306 may be referred to an encapsulant volume 364, while the volume above line 306 may be referred to as a void volume 366, which combined define the casing volume 354. In the depicted configuration, the encapsulant volume 364 is defined at least in part by portions of certain walls 352 of the case 310 that are in contact with the encapsulant 356, as well as the expansion component 358, which in this example is secured to the face cover 312. Also in the depicted configuration, the void volume 366 is defined at least in part by portions of certain walls 352 of the case 310 that are above an upper surface of the encapsulant 356, as defined by the line 306. Further, in FIG. 4B, the expansion component 358 projects at least partially into the void volume 366. This helps ensure that the encapsulant 356 does not inadvertently extend above the compressible layer 360.

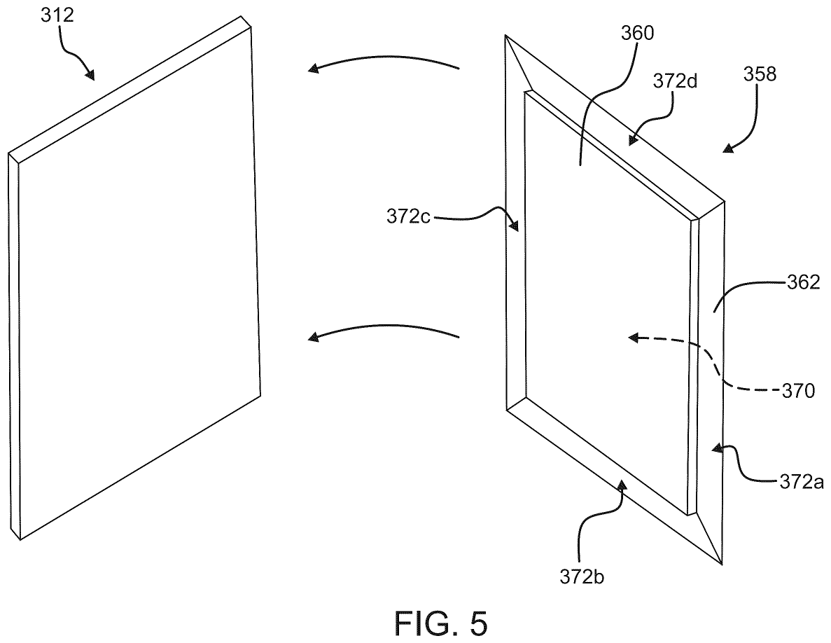

FIG. 5 depicts a portion of a power supply casing (in this example, face cover 312) and an expansion component 358 utilized in the high voltage isolation case of FIGS. 4A and 4B. As noted elsewhere herein, the expansion component 358 includes a compressible layer 360 and a conductive layer 362. In examples, a robust chemical adhesive may be disposed on the exposed surface of either or both of the compressible layer 360 and the conductive layer 362 and may be used to adhere the expansion component 358 to the face cover 312. In one example, multiple discrete areas of adhesion may be present on the conductive layer 362, each covered by a non-adhesive film or cover. For example, a central adhesive location 370 may correspond to an area where the compressible layer 360 is to be located. During manufacturing, a non-adhesive contact film disposed thereon may be removed, the adhesive exposed, and the compressible layer 360 adhered thereto. Thereafter, non-adhesive contact films at each of the edge areas 372a-d may be removed so as to expose the adhesive, after which those edge areas 372a-d may be secured to the face cover 312. Thereafter, the face cover 312 may be secured to walls of the case, such as depicted in FIG. 4B.

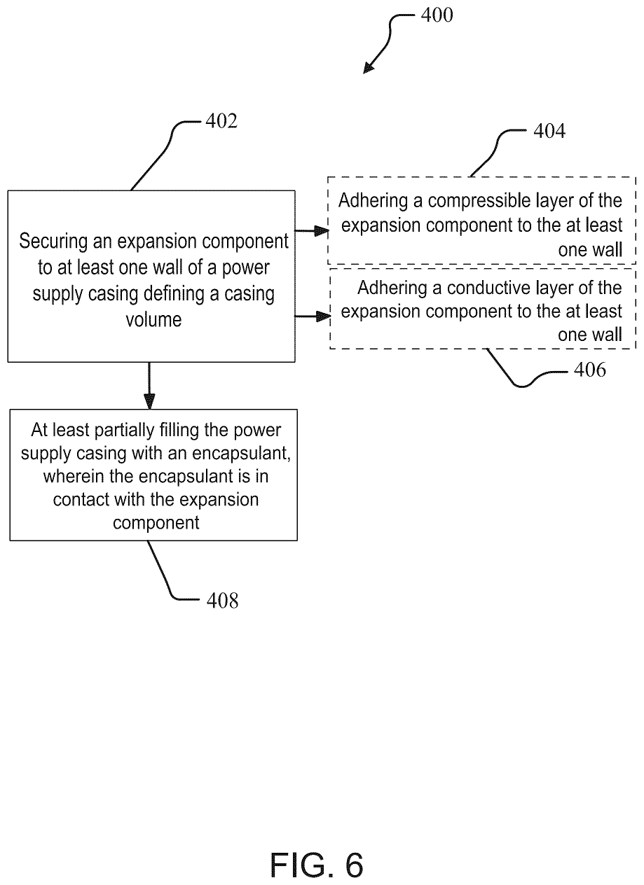

FIG. 6 depicts a method 400 of manufacturing a power supply, such as the power supplies for mass spectrometers discussed herein. The methods described in the context of FIG. 6 may also be utilized to manufacture other power supplies for other equipment requiring robust electrical isolation and/or thermal expansion capability for circuits or portions thereof. Aspects of the method 400 are described elsewhere herein, e.g., at FIG. 5. The method 400 begins with securing an expansion component to at least one wall of a power supply casing, operation 402. The wall may be selected as required or desired for a particular application. Considerations relevant to the selection of an appropriate wall include, but are not limited to, ease of manufacturing or assembly, anticipated direction of thermal expansion, available wall area (to enable appropriate distribution of expansion forces), etc. A plurality of assembled walls define a case having a casing volume. Securing of the expansion component may be performed by adhering one or more layers of the expansion component to the at least one wall. For example, operation 404 contemplates adhering a compressible layer of the expansion component to the at least one wall. In another example, operation 406 contemplates adhering a conductive layer of the expansion component to the at least one wall. In other examples, both layers may be adhered to the at least one wall.

Examples of the present method 400 include repeating operations 402-406 for any number of walls of the casing as required or desired. Factors associated with selecting more than one wall (as well as the location of individual walls relative to each other) are described above in the context of operation 402. Encapsulants having particularly large expansion capabilities (e.g., due to high heat generation within the casing or encapsulant material properties) may make utilizing a greater number of expansion components (or expansion components having a thicker compressible layer) more desirable. The method 400 continues with operation 408, at least partially filling the power supply casing with an encapsulant, wherein the encapsulant is in contact with the expansion component. In examples, a conductive layer of the expansion component is disposed between the encapsulant and a compressible layer of the expansion component. This disposition biases the conductive layer against the encapsulant.

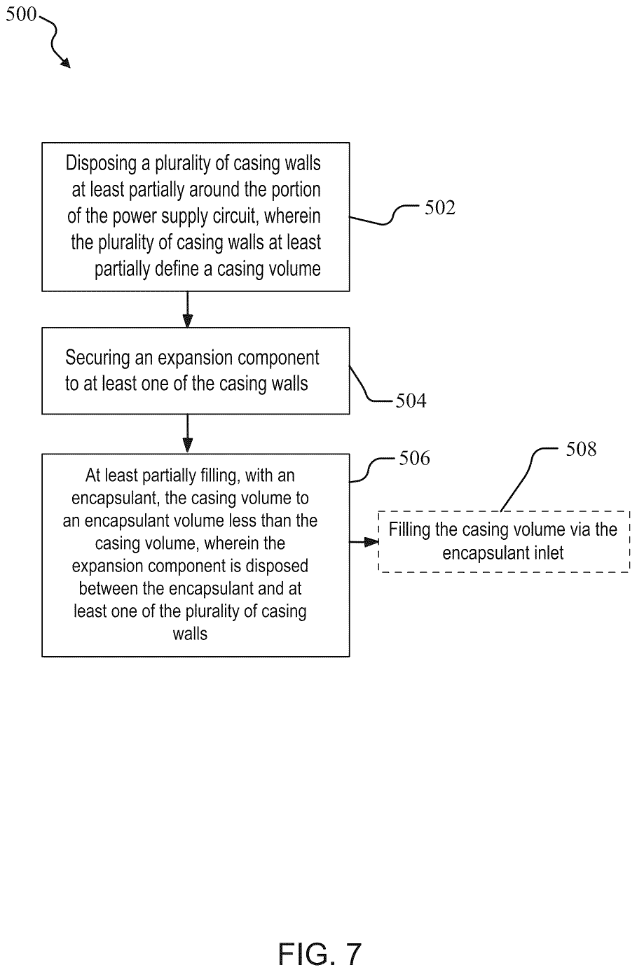

FIG. 7 depicts a method 500 of encapsulating at least a portion of a power supply circuit for a mass spectrometer. The method 500 begins with operation 502, disposing a plurality of casing walls at least partially around the portion of the power supply circuit. As noted above, the plurality of casing walls at least partially define a casing volume. The method 500 proceeds to operation 504, securing an expansion component to at least one of the casing walls. The expansion component may be configured as described herein and may include a conductive layer such as a metallic foil and a compressible layer, such as a foam. In examples, the expansion component may be secured to a cover (or otherwise easily accessible wall) of the plurality of walls. Thereafter, the cover bearing the expansion component may be secured to the remaining walls, effectively or nearly closing the casing and defining a casing volume (e.g., the entire interior volume of the casing). Thereafter, the method 500 includes at least partially filling, with an encapsulant, the casing volume to an encapsulant volume. The encapsulant volume is the volume within the casing occupied by the encapsulant and, in examples, is less than the casing volume. In still other examples, the encapsulant may completely fill the casing volume, thus making the encapsulant volume the same as the casing volume. The encapsulant may be introduced to the interior of the casing via any opening available, but in examples may be flowed into the casing interior via an encapsulant inlet in one of the plurality of walls, as contemplated in operation 508. The encapsulant is introduced in such a way so as to dispose the expansion component between the encapsulant and at least one of the plurality of casing walls.

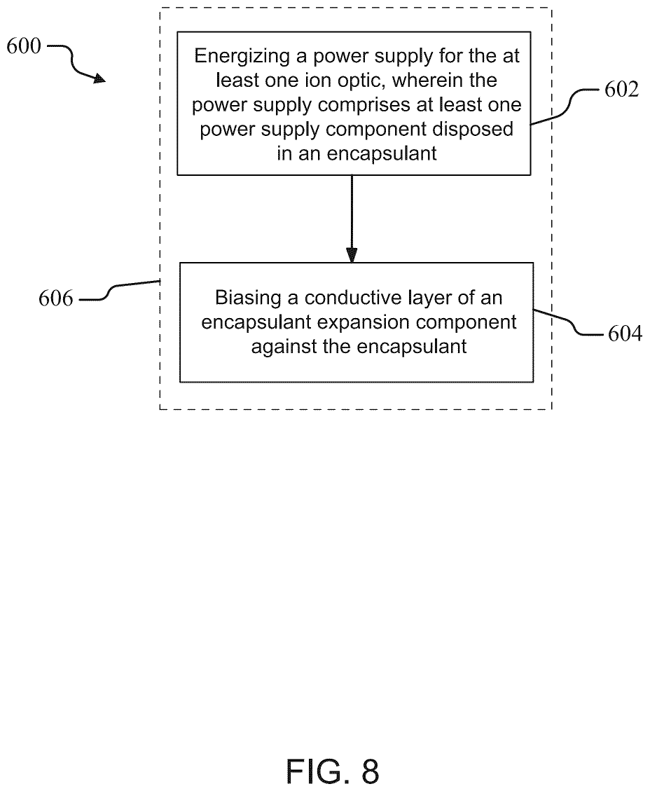

As described herein, use of the expansion components such as described herein improves performance of systems that utilize high voltage power circuits. The expansion component allows for encapsulant expansion during operation of a high voltage power supply, thereby reducing stress on the electrical components, which can result in drift, so as to improve system performance. As such, FIG. 8 depicts a method 600 of powering at least one ion optic of a mass spectrometer. The method 600 includes, in operation 602, energizing a power supply for the at least one ion optic. The power supply may include at least one power supply component disposed in an encapsulant. Thus, the method 600 also contemplates operation 604, biasing a conductive layer of an encapsulant expansion component against the encapsulant. As depicted by dashed box 606, operations 602 and 604 are performed substantially simultaneously.

FIG. 9 depicts a block diagram of a computing device similar to the computing system 103 discussed above with respect to FIG. 1. In the illustrated example, the computing device 700 may include a bus 702 or other communication mechanism of similar function for communicating information, and at least one processing element 704 (collectively referred to as processing element 704) coupled with bus 702 for processing information. As will be appreciated by those skilled in the art, the processing element 704 may include a plurality of processing elements or cores, which may be packaged as a single processor or in a distributed arrangement. Furthermore, a plurality of virtual processing elements 704 may be included in the computing device 700 to provide the control or management operations for, e.g., the mass analysis systems illustrated above.

The computing device 700 may also include one or more volatile memory(ies) 706, which can for example include random access memory(ies) (RAM) or other dynamic memory component(s), coupled to one or more busses 702 for use by the at least one processing element 704. Computing device 700 may further include static, non-volatile memory(ies) 708, such as read only memory (ROM) or other static memory components, coupled to busses 702 for storing information and instructions for use by the at least one processing element 704. A storage component 710, such as a storage disk or storage memory, may be provided for storing information and instructions for use by the at least one processing element 704. As will be appreciated, the computing device 700 may include a distributed storage component 712, such as a networked disk or other storage resource available to the computing device 700.

The computing device 700 may be coupled to one or more displays 714 for displaying information to a user. Optional user input device(s) 716, such as a keyboard and/or touchscreen, may be coupled to Bus 702 for communicating information and command selections to the at least one processing element 704. An optional cursor control or graphical input device 718, such as a mouse, a trackball or cursor direction keys for communicating graphical user interface information and command selections to the at least one processing element. The computing device 700 may further include an input/output (I/O) component, such as a serial connection, digital connection, network connection, or other input/output component for allowing intercommunication with other computing components and the various components of, e.g., the mass analysis systems discussed above.

In various examples, computing device 700 can be connected to one or more other computer systems via a network to form a networked system. Such networks can for example include one or more private networks or public networks, such as the Internet. In the networked system, one or more computer systems can store and serve the data to other computer systems. The one or more computer systems that store and serve the data can be referred to as servers or the cloud in a cloud computing scenario. The one or more computer systems can include one or more web servers, for example. The other computer systems that send and receive data to and from the servers or the cloud can be referred to as client or cloud devices, for example. Various operations of, e.g., the mass analysis systems 100 and 200 may be supported by operation of the distributed computing systems.

The computing device 209 discussed above with respect to FIG. 2, similar to the computing device 700, may be operative to control operation of the components of the mass analysis system 200 and the sampling system 204 through a communication device such as, e.g., communication device 720, and to handle data generated by components of the mass analysis system 200 through the data processing system 200.

In some examples, analysis results are provided by the computing device 700 in response to the at least one processing element 704 executing instructions contained in memory 706 or 708 and performing operations on data received from the mass analysis system 200. Execution of instructions contained in memory 706 and/or 708 by the at least one processing element 704 can render, e.g., the mass analysis systems 100 and 200 and associated sample delivery components operative to perform methods described herein.

The term “computer-readable medium” as used herein refers to any media that participates in providing instructions to the processing element 704 for execution. Such a medium may take many forms, including but not limited to, non-volatile media, volatile media, and transmission media. Non-volatile media includes, for example, optical or magnetic disks, such as disk storage 710. Volatile media includes dynamic memory, such as memory 706. Transmission media includes coaxial cables, copper wire, and fiber optics, including the wires that include bus 702.

Common forms of computer-readable media or computer program products include, for example, a floppy disk, a flexible disk, hard disk, magnetic tape, or any other magnetic medium, a CD-ROM, digital video disc (DVD), a Blu-ray Disc, any other optical medium, a thumb drive, a memory card, a RAM, PROM, and EPROM, a FLASH-EPROM, any other memory chip or cartridge, or any other tangible medium from which a computer can read.

Various forms of computer readable media may be involved in carrying one or more sequences of one or more instructions to the processing element 704 for execution. For example, the instructions may initially be carried on the magnetic disk of a remote computer. The remote computer can load the instructions into its dynamic memory and send the instructions over a telephone line using a modem. A modem local to computing device 700 can receive the data on the telephone line and use an infra-red transmitter to convert the data to an infra-red signal. An infra-red detector coupled to bus 702 can receive the data carried in the infra-red signal and place the data on bus 702. Bus 702 carries the data to memory 706, from which the processing element 704 retrieves and executes the instructions. The instructions received by memory 706 and/or memory 708 may optionally be stored on storage device 710 either before or after execution by the processing element 704.

In accordance with various examples, instructions operative to be executed by a processing element to perform a method are stored on a computer-readable medium.

The computer-readable medium can be a device that stores digital information. For example, a computer-readable medium includes a compact disc read-only memory (CD-ROM) as is known in the art for storing software. The computer-readable medium is accessed by a processor suitable for executing instructions configured to be executed. This disclosure described some examples of the present technology with reference to the accompanying drawings, in which only some of the possible examples were shown. Other aspects can, however, be embodied in many different forms and should not be construed as limited to the examples set forth herein. Rather, these examples were provided so that this disclosure was thorough and complete and fully conveyed the scope of the possible examples to those skilled in the art.

Although specific examples were described herein, the scope of the technology is not limited to those specific examples. One skilled in the art will recognize other examples or improvements that are within the scope of the present technology. Therefore, the specific structure, acts, or media are disclosed only as illustrative examples. Examples according to the technology may also combine elements or components of those that are disclosed in general but not expressly exemplified in combination, unless otherwise stated herein. The scope of the technology is defined by the following claims and any equivalents therein.

1. A mass spectrometer comprising:
at least one ion optic for influencing the trajectory of at least one ion in an ionized sample;
a casing comprising a plurality of walls;
power supply components disposed in the casing for supplying power to the at least one ion optic;
an expansion component within the casing; and
an encapsulant disposed in the casing and encapsulating the power supply components, and wherein the encapsulant is in contact with the expansion component.

2. The mass spectrometer of claim 1, wherein the expansion component comprises a compressible layer and a conductive layer, wherein the compressible layer is in contact with at least one wall of the plurality of walls, and wherein the conductive layer is disposed on a side of the compressible layer opposite the at least one wall, and wherein the encapsulant is in contact with the conductive layer.

3. (canceled)

4. The mass spectrometer of claim 1, wherein the casing defines a casing volume and wherein the encapsulant comprises an encapsulant volume less than the casing volume.

5-7. (canceled)

8. The mass spectrometer of claim 2, wherein the compressible layer comprises at least one of a bladder, a bellows, a foam, and a bead.

9. The mass spectrometer of claim 1, wherein the expansion component is secured to at least two walls of the plurality of walls.

10. The mass spectrometer of claim 1, wherein the expansion component is secured to the at least one wall via the conductive layer.

11. The mass spectrometer of claim 1, wherein the casing and an exposed surface of the encapsulant at least partially define a void volume and wherein the expansion component extends into the void volume.

12. (canceled)

13. A method of encapsulating at least a portion of a power supply circuit for a mass spectrometer, the method comprising:
disposing a plurality of casing walls at least partially around the portion of the power supply circuit, wherein the plurality of casing walls at least partially define a casing volume;
securing an expansion component to at least one of the casing walls; and
at least partially filling, with an encapsulant, the casing volume to an encapsulant volume less than the casing volume, wherein the expansion component is disposed between the encapsulant and at least one of the plurality of casing walls.

14. The method of claim 13, wherein the at least one of the plurality of casing walls comprises a face cover secured to a plurality of perimeter walls of the plurality of casing walls.

15. The method of claim 14, wherein the expansion component comprises a conductive layer for securing the expansion component to the face cover, and wherein a compressible layer of the expansion component is disposed between the conductive layer and the face cover.

16. The method of claim 14, wherein at least one of the plurality of casing walls defines a encapsulant inlet, and wherein filling the casing volume with the encapsulant comprises filling the casing volume via the encapsulant inlet.

17. The method of claim 13, further comprising securing an access cover to the plurality of casing walls, wherein the access cover defines a vent opening.

18. The method of claim 17, wherein the encapsulant volume is below a lowermost edge of the access cover.

19. The method of claim 13, wherein the expansion component projects from the encapsulant volume.

20. The method of claim 13, further comprising securing to the plurality of casing walls, the at least one casing wall having secured thereto the expansion component.

21. The method of claim 13, wherein the compressible layer comprises at least one of a bladder, a bellows, a foam, and a bead.

22. (canceled)

23. A method of manufacturing a power supply, the method comprising:
securing an expansion component to at least one wall of a power supply casing defining a casing volume; and
at least partially filling the power supply casing with an encapsulant, wherein the encapsulant is in contact with the expansion component.

24. The method of claim 23, wherein securing the expansion component to the at least one wall of the power supply casing comprises adhering a compressible layer of the expansion component to the at least one wall.

25. The method of claim 23, wherein securing the expansion component to the at least one wall of the power supply casing comprises adhering a conductive layer of the expansion component to the at least one wall.

26. The method of claim 23, wherein a compressive layer of the expansion component is disposed against the at least one wall and biases a conductive portion of the expansion component against the encapsulant.

27. (canceled)
